(19) United States
(12) Patent Application Publication
(10) Pub. No.: US 2025/0390161 A1
(43) Pub. Date: Dec. 25, 2025

(54) ELECTRONIC DEVICE, CONTROL METHOD, AND STORAGE MEDIUM

(71) Applicant: Lenovo (Beijing) Limited, Beijing (CN)

(72) Inventors: Mingzhe HUANG, Beijing (CN); Ruizhi WANG, Beijing (CN)

(21) Appl. No.: 19/245,860

(22) Filed: Jun. 23, 2025

(30) Foreign Application Priority Data
Jun. 24, 2024 (CN) 202410823830.8

(51) Int. Cl. G06F 1/3234; G01S 17/04; G01S 17/08; H03K 17/945

(52) U.S. Cl. CPC G06F 1/3265; G01S 17/04; G01S 17/08; H03K 17/945

(57) ABSTRACT

An electronic device, a control method, and a storage medium are provided in the present disclosure. The electronic device a frame body; a display screen, including an inner edge and an outer edge; a transmitter, disposed at a first position of the frame body and configured to transmit a target signal, where a transmitting end surface of the transmitter is in a first target region formed by the inner edge of the display screen; and a receiver, disposed at a second position of the frame body and configured to receive the target signal. A receiving end surface of the receiver corresponds to a second target region of the display screen; a transmittance of the first target region is greater than a transmittance of the second target region; and the target signal is configured to characterize that presence of an object is within a target range outside the electronic device.

### CROSS-REFERENCE TO RELATED APPLICATION

This application claims the priority of Chinese Patent Application No. 202410823830.8, filed on Jun. 24, 2024, the content of which is incorporated herein by reference in its entirety.

### TECHNICAL FIELD

The present disclosure generally relates to the field of electronic device technology, and, more particularly, relates to an electronic device, a control method, and a storage medium.

### BACKGROUND

For an electronic device (e.g., an electronic device with full screen), in order to identify whether an object is outside the electronic device, an under-screen distance sensor (e.g., a proximity (P) sensor) may be selected to achieve such effect. However, due to limitations such as the screen structure, a transmitter of the distance sensor may be blocked by the screen when transmitting signal waves, which may greatly reduce the energy.

### SUMMARY

One aspect of the present disclosure provides an electronic device. The electronic device includes a frame body; a display screen, disposed on an outer surface of the frame body, where the display screen includes an inner edge and an outer edge; a transmitter, disposed at a first position of the frame body and configured to transmit a target signal, where a transmitting end surface of the transmitter is in a first target region formed by the inner edge of the display screen; and a receiver, disposed at a second position of the frame body and configured to receive the target signal, where a receiving end surface of the receiver corresponds to a second target region of the display screen; a transmittance of the first target region is greater than a transmittance of the second target region; and the target signal, received by the receiver, is configured to characterize that a presence of an object is within a target range outside the electronic device.

Another aspect of the present disclosure provides a control method. The control method includes obtaining a trigger instruction; and in response to the trigger instruction, enabling a transmitter of an electronic device to transmit a target signal and enabling a receiver of the electronic device to obtain the target signal, where the target signal, received by the receiver, is configured to characterize that a presence of an object is within a target range outside the electronic device. A transmitting end surface of the transmitter is in a first target region formed by an inner edge of a display screen of the electronic device, a receiving end surface of the receiver corresponds to a second target region of the display screen, and a transmittance of the first target region is greater than a transmittance of the second target region.

Another aspect of the present disclosure provides a non-transitory computer-readable storage medium containing a computer program that when being executed, causes one or more processors to perform a control method. The control method includes obtaining a trigger instruction; and in response to the trigger instruction, enabling a transmitter of an electronic device to transmit a target signal and enabling a receiver of the electronic device to obtain the target signal, where the target signal, received by the receiver, is configured to characterize that a presence of an object is within a target range outside the electronic device. A transmitting end surface of the transmitter is in a first target region formed by an inner edge of a display screen of the electronic device, a receiving end surface of the receiver corresponds to a second target region of the display screen, and a transmittance of the first target region is greater than a transmittance of the second target region.

Other aspects of the present disclosure may be understood by those skilled in the art in light of the description, the claims, and the drawings of the present disclosure.

### BRIEF DESCRIPTION OF THE DRAWINGS

In order to more clearly illustrate the technical solution of the embodiment of the present disclosure, the following is a brief introduction to the drawings required for use in the embodiment. Obviously, the drawings described below are some embodiments of the present disclosure. For ordinary technicians in this field, other drawings may also be obtained based on these drawings without creative work.

FIGS. 1A and 1B illustrate structural schematics of examples of electronic device according to various embodiments of the present disclosure.

FIG. 2 illustrates a schematic of a signal radiation range of an electronic device according to various embodiments of the present disclosure.

FIG. 3 illustrates a schematic of a use attitude of an electronic device according to various embodiments of the present disclosure.

FIG. 4 illustrates another schematic of a use attitude of an electronic device according to various embodiments of the present disclosure.

FIG. 5 illustrates another schematic of a use attitude of an electronic device according to various embodiments of the present disclosure.

FIG. 6 illustrates a partial structural schematic of an electronic device according to various embodiments of the present disclosure.

FIG. 7 illustrates a schematic of signal radiation parameters of an electronic device according to various embodiments of the present disclosure.

FIG. 8 illustrates a flowchart of a control method according to exemplary embodiment two of the present disclosure.

### DETAILED DESCRIPTION

Various embodiments of the present disclosure are described in detail in conjunction with accompanying drawings hereinafter, which may not be intended to limit the present disclosure.

It may be understood that various modifications may be made to embodiments disclosed herein. Therefore, the present specification should not be considered as the limitation, but only as exemplary embodiments. Those skilled in the art may made other modifications within the scope of the present disclosure.

Accompanying drawings, which are included in and constitute a part of the present specification, may illustrate embodiments of the present disclosure; and together with above description of the present disclosure and detailed description of embodiments given below, may be used to explain the principles of the present disclosure.

The features and the like of the present disclosure may become apparent through following description of optional forms of embodiments given as non-limiting examples with reference to accompanying drawings.

It may also be understood that although the present disclosure has been described with reference to certain specific examples, those skilled in the art may implement various other equivalent forms of the present disclosure which may have the features described in claims and be within the protection scope defined thereby.

Above-mentioned and other aspects, features and advantages of the present disclosure may become more apparent when following detailed description is combined with accompanying drawings.

Embodiments of the present disclosure are described hereinafter with reference to accompanying drawings. However, it may be understood that disclosed embodiments may be merely examples of the present disclosure, which may be implemented in various manners. Well-known and/or repeated functions and structures may be not described in detail to avoid unnecessary or redundant details that make the present disclosure unclear. Therefore, the structural and functional details disclosed herein may be not intended to be the limitation but may be merely used as representative and claim basis to make those skilled in the art substantially use the present disclosure in various manner with any appropriate detailed structure.

In the present disclosure, the terms “in one embodiment”, “in another embodiment” or “in other embodiments” may refer to one or more of same or different embodiments according to the present disclosure.

Various embodiments of the present disclosure are described in detail in conjunction with accompanying drawings hereinafter.

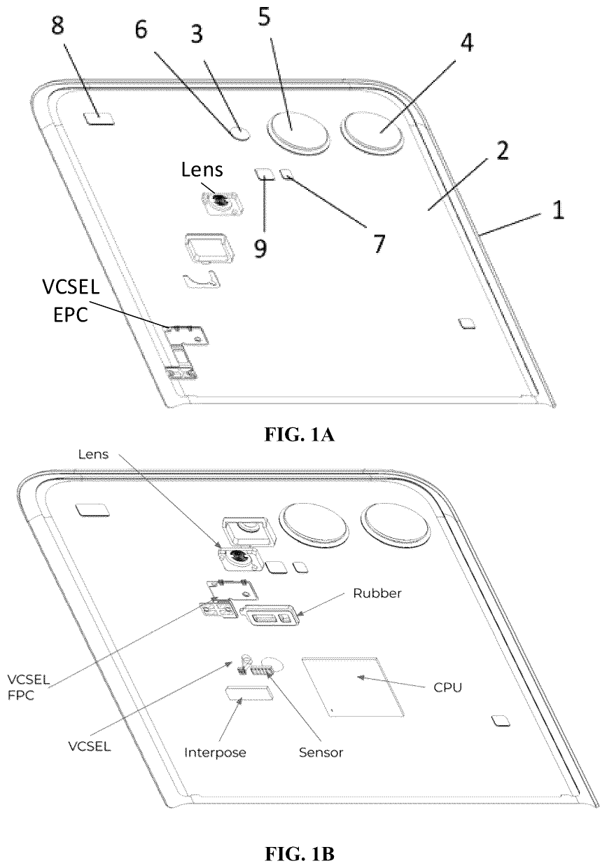

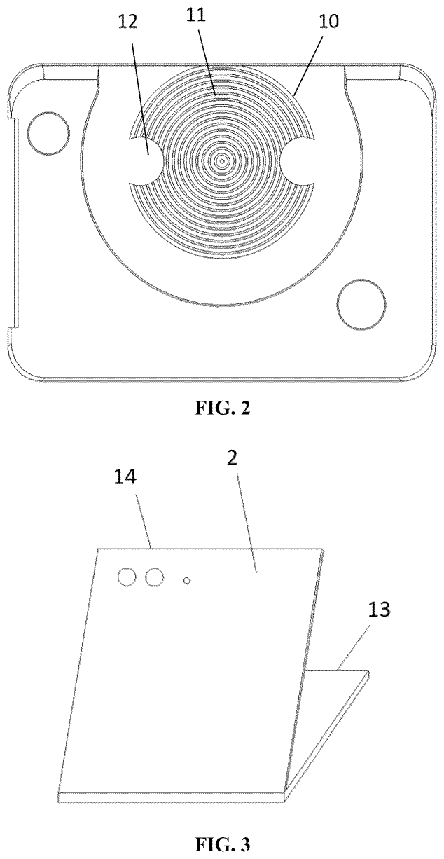

FIGS. 1A and 1B illustrate structural schematics of examples of electronic device according to various embodiments of the present disclosure. As shown, an exemplary electronic device may include a frame body 1; a display screen 2 disposed on the outer surface of the frame body 1, where the display screen 2 may include an inner edge and an outer edge; a transmitter disposed at the first position of the frame body 1, where the transmitting end surface of the transmitter may be in the first target region formed by the inner edge of the display screen 2 and may be configured to transmit a target signal; and a receiver disposed at the second position of the frame body 1 and configured to receive the target signal. The receiving end surface of the receiver may correspond to the second target region of the display screen 2. The transmittance of the first target region may be greater than the transmittance of the second target region; and the receiver may receive the target signal indicating that a presence of an object is within the target range outside the device.

Based on the above, it should be known that the electronic device of one embodiment may at least include the frame body 1, the display screen 2, the transmitter and the receiver. The frame body 1 may be considered as a body frame of the electronic device, or a body without a display screen 2, which may not limit structural form. For example, the frame body 1 may be a body formed by rotatory connection of two main bodies, or a straight-type body, or a flexible body (e.g., a body with the flexible display screen 2 or a bending body), and the like. The display screen 2 may be configured on the outer surface of the frame body 1, and the display screen 2 may include the outer edge and the inner edge. The inner edge may be formed by a hole, a hollow region or the like configured at the display screen 2. The inner edge described in one embodiment may be a structure that the display screen 2 already has and may be not formed by a hole, a hollow region or the like which is additional configured. The transmitter may be a laser transmitter (e.g., using a vertical cavity surface-emitting laser (VCSEL) as shown in FIGS. 1A-1B) or another type of transmitter, which may not be limited in the present disclosure. The transmitter may be configured at the first position of the frame body 1, and the transmitting end surface of the transmitter may be in the first target region surrounded by the inner edge of the display screen 2. For example, the transmitting end surface may be embedded in the first target region. The transmitting end surface may be in parallel with or coplanar with the plane where the first target region is located, that is, may be coplanar with the display screen 2. The transmitter may be configured to transmit the target signal outward. The receiver may be an infrared receiver or another type of receiver, which may be not limited in the present disclosure. The receiver may be configured at the second position of the frame body 1 to receive reflected target signal. The receiving end surface of the receiver may correspond to the second target region of the display screen 2. The position of the second target region may be not limited in the present disclosure and may need to be determined systematically according to the field of view of the receiver, the field of view of the transmitter, and the range of the region to be detected. The second target region in one embodiment may be in the region surrounded by the outer edge and the inner edge of the display screen 2. The first target region may be surrounded by the inner edge of the display screen 2, and the inner edge may be formed by a through hole, a hollow region or the like, that is, the display screen 2 in corresponding region may be in a pass-through state or a nearly pass-through state. Therefore, the transmittance of the first target region may be high; and the transmittance of the first target region may be greater than the transmittance of the region between the inner edge and the outer edge of the display screen 2, that is, the transmittance of the first target region may be greater than the transmittance of the second target region. Based on the above, when the transmitter emits (i.e., transmits) the target signal outward, the energy may not be greatly reduced, such that the target signal may be radiated over long distance, thereby implementing the detection of long-distance objects outside the device.

Based on the above, it should be known that for the electronic device in one embodiment, the transmittance of corresponding region of the under-screen transmitter may be improved by utilizing or reusing existing holes of the display screen 2 while the display screen 2 maintains original structure and no additional holes are formed. In such way, the transmitter may radiate high-energy signal waves and cooperate with the receiver to complete the object detection in the long-distance region outside the device; the under-screen transmitter and the receiver of the electronic device may implement the object detection in the long-distance region and the object detection in the short-distance region to enhance the distance detection function of the electronic device, thereby providing technical basis for more detection and identification functions of the electronic device.

In one embodiment, the display screen 2 may include, but may be not limited to, glass, a liquid crystal layer, an optical adhesive layer, a circuit layer, a cover film, . . . , and a copper layer from the outside to the inside. The inner edge of the display screen 2 may be formed by the holes, the through holes or the like passing through the glass and the copper layer or only passing through the liquid crystal layer and the copper layer without penetrating the glass. Both forms may be applicable in the present disclosure. The transmittance of the glass may be extremely strong. Therefore, even in response to that the holes, the through holes or the like do not pass through the glass, the loss of transmittance may be ignored.

In another embodiment, the electronic device may further include a shared part configured to share the first target region with the transmitter.

The shared part may include one of the following: the first light-emitting element 3 disposed at the third position of the frame body 1, or the first camera 4 disposed at the fourth position of the frame body 1, or the second camera 5 disposed at the fifth position of the frame body 1. The transmitter may be between the fourth position and the fifth position.

Exemplarily, the electronic device in one embodiment may further include the shared part configured to share the first target region with the transmitter, and the shared part may be considered as that the first target region may be configured for the use of the shared part. The transmitter may reuse the first target region to transmit the target signal. For example, the shared part may be the first light-emitting element 3, which may be, but may be not limited to, a flash. The shared part may be configured at the third position of the frame body 1, and the third position may correspond to the first target region. For example, the first target region may cover both the third position and the first position. In actual application, the first light-emitting element 3 and the transmitter may be arranged to be in parallel or approximately in parallel with each other (at least the projections of the first light-emitting element 3 and the transmitter in the first target region may be in parallel or approximately in parallel with each other); the first light-emitting element 3 may use a part of the first target region to emit light; and the transmitter may use another part of the first target region to radiate (e.g., project) the target signal.

Or when the electronic device includes two cameras, such as the first camera 4 and the second camera 5 arranged to be adjacent to each other, two cameras may be respectively located at the fourth position and the fifth position of the frame body 1; or the electronic device may include more cameras which may be respectively arranged at different positions of the frame body 1. Although the region of the display screen 2 between the two adjacent cameras has display function, such region of the display screen 2 may be interfered by the cameras, and the user's visual effect may be not desirable. Moreover, the camera may be located at the edge or top corner of the screen which may be the region that the user does not pay significant attention to. Therefore, the hole or hollow region may be configured between two or more adjacent cameras for assembling the transmitter, which may not only satisfy the transmittance requirement of the target signal but also may not affect the user's viewing of the content displayed on the display screen 2, that is, may not affect the user's visual experience.

Based on above-mentioned embodiments, it should be known that the transmitter of the present disclosure may implement the transmission of the target signal based on reusing original hole structure of the display screen 2; and may implement the transmission of the target signal based on configuring the hole or other structure at the region of the display screen 2 with less display significance and poor display effect (e.g., the region between two or more cameras).

For example, in one application embodiment, a lens 10 may be configured between the first light-emitting element 3 and the first target region on the frame body 1. The lens 10 may be embedded in the display screen 2 to block the first target region. The transmitter may be configured around the first light-emitting element 3. Taking the light signal wave emitted by the transmitter as an example, when both the transmitter and the first light-emitting element 3 emit light beams, the light beams may pass through the lens 10 to be transmitted out of the electronic device. In one embodiment, the lens 10 may include the first region 11, where the first region 11 may be configured for the first light-emitting element 3, and the first region 11 may include the first texture; and further include the second region 12, where the second region 12 may be configured for the transmitter.

As shown in FIG. 2, the quantity of second regions 12 may be multiple, which may match the quantity of transmitters. That is, when the quantity of transmitters is multiple, the quantity of second regions 12 may be also multiple. In addition, the multiple second regions 12 may correspond to the multiple transmitters respectively, thereby transmitting the signal waves emitted by corresponding transmitters. The second region 12 may be in the first region 11, that is, the second region 12 may be a partial region of the first region 11. In one embodiment, the first region 11 may include the first texture, and the second region 12 may include the second texture. The first texture and the second texture may not only be configured to assist in transmitting the light emitted by the first light-emitting element 3, but also may play a certain blocking role which may prevent the user from seeing the device structure behind the lens 10 when viewing from the outside of the display screen 2 to the inside of the display screen 2. In one embodiment, the first texture may be a part of a plurality of concentric first circles, and the second texture may be a part of a plurality of concentric second circles. The first circle and the second circle may be same circle or different circles. When the first circle and the second circle are the same circle, the first texture and the second texture may cooperate to form a plurality of complete circles. Or the second texture may also be formed by coating with a coating material having light-transmitting properties. Through such formation manner, the target signal emitted by the transmitter may be exited through the second region 12, but the user cannot see the internal structure of the device through the second region 12 from outside the display screen 2.

In another application embodiment, the display screen 2 may include a light-transmitting plate (e.g., glass) on the outside, which may cover entire display screen 2. A corresponding inner edge may be also configured at an inner edge position of the light-transmitting plate corresponding to the display screen 2. For example, an opening may be also configured at an opening position of the light-transmitting plate corresponding to the display screen 2; and the edges (i.e., inner edges) of two openings may correspond to each other. The inner edge of the light-transmitting plate may form the third target region which may correspond to the first target region on the display screen 2; and the lens 10 may be configured on the third target region. In order to prevent light from emitting from the inner edge of the light-transmitting plate (e.g., light leakage), in one embodiment, a blocking part may be further configured at the inner edge of the light-transmitting plate, and the first region 11 of the lens 10 may correspond to the inner edge of the blocking part. For example, the blocking part may be a circular ring which may be configured (e.g., sealed) between the lens 10 and the inner edge corresponding to the light-transmitting plate. For another example, the blocking part may be a cylindrical shape with both ends open, which may be adaptively embedded in regions of the display screen 2 and the light-transmitting plate corresponding to the openings (e.g., the first target region and the third target region corresponding to the positions). That is, the regions of the openings corresponding to the display screen 2 and the light-transmitting plate may form a cylindrical chamber, and the blocking part may match the cylindrical chamber (structure) and be correspondingly embedded in the cylindrical chamber. The end of the blocking part facing the outside of the device may match the shape of the lens 10 and be closely attached to each other. In such way, the transmitter, the first light-emitting element 3 and the like may be sealed in the cylindrical chamber, and the transmitter and other devices cannot be viewed from the outside; and the light may only be emitted through the lens 10. No connection gap may be at the edge of the lens 10, such that no light may be transmitted.

Or the blocking part may be a blocking region formed by extending the first distance from the third target region of the light-transmitting plate to the center; and the first region 11 of the lens 10 may correspond to the inner edge of the blocking region. The light of the second light-emitting element may pass through the blocking region, the first portion of the second light-emitting element may correspond to the second region 12 of the lens 10, and the second portion of the second light-emitting element may correspond to a part of the blocking region. For example, the blocking part may be a light-transmitting coating layer coated on the edge of the lens 10; and such coating layer may allow light to be exited, but the user cannot see the inside of the display screen 2 from outside the display screen 2 through the coating layer. Obviously, the coating may also be a non-light-transmitting coating layer, such that that light may be prevented from being exited from the coating layer.

Furthermore, the electronic device may at least include two transmitters. The two transmitters may include the first transmitter 6 which is located at the first position and corresponds to the first target region; and the second transmitter 7 which is located at the sixth position and corresponds to the third target region, where the third target region may have same transmittance as the second target region.

The first transmitter 6 and the receiver may satisfy the first distance, the second transmitter and the receiver may satisfy the second distance, and the first distance may be greater than the second distance.

In one embodiment, the first transmitter 6 may cooperate with the receiver to form a detector for detecting whether an object is in a long-distance region, such that the first transmitter 6 may need to ensure that the target signal radiated has high energy and is capable of being radiated to a relatively-long-distance region. To achieve such effect, the first transmitter 6 may be configured at the first position corresponding to the first target region, which may prevent the energy of the target signal being reduced by the display screen 2 when the target signal is radiated. The second transmitter 7 may cooperate with the receiver to form a detector for detecting whether an object is in a short-distance region, such that the second transmitter 7 may need to ensure that the target signal radiated has low energy and is capable of only being radiated to a relatively-short-distance region. To achieve such effect, the second transmitter 7 may be configured at the sixth position corresponding to the third target region. The transmittance of the third target region may be lower than that of the first target region. Therefore, when the second transmitter 7 radiates the target signal, the energy may be reduced by the display screen 2, which may result in that the energy of the target signal is relatively low, and the target signal is only be radiated to a relatively-short-distance region.

In actual application, the first transmitter 6 may be configured at a position sharing the first target region with the first light-emitting element 3 or may be configured at the hole formed in the display screen 2 between two adjacent cameras of the electronic device; and the transmittance of the first target region may be as high as about 90%. The second transmitter 7 may be configured in the display screen 2. Optionally, the second transmitter may be configured in a non-main-display region, for example, the region between two cameras or the like. At a region corresponding to the configuration position of the second transmitter 7, a supporting part (e.g., copper sheet) on the side of the display screen 2 facing the inside of the device may be removed, such that the display screen 2 may have a specified transmittance (e.g., a transmittance of 5%), while still having a display function. That is, the configuration position of the second transmitter 7 may still have display function.

When the positions of the first transmitter 6, the second transmitter 7 and the receiver are configured, the first distance may be between the first transmitter 6 and the receiver, and the second distance may be between the second transmitter 7 and the receiver. The radiation distance may be proportional to the distance between the transmitter and the receiver, such that the first distance may be greater than the second distance. The configuration positions of the transmitter and the receiver may need to be determined systematically according to the combination of the field of view of each transmitter, the field of view of the receiver, and the distance between the region to be detected and the display screen 2, which may ensure that the target signals transmitted by different transmitters may be successfully radiated to corresponding detection regions. The combination of different transmitters and receivers may only be configured to detect whether there are objects in corresponding detection regions through the field-of-view blind spots (regions) and may not interfere with the detection of other detection regions by other combinations. Referring to FIG. 6, TX1 may be the first transmitter 6, TX2 may be the second transmitter 7, RX1 may be the receiver, the field-of-view blind spot between the first transmitter 6 and the receiver may be the detection region of the second transmitter 7, and the field-of-view (detection) blind spot between the second transmitter 7 and the receiver may be the detection region of the first transmitter 6. Therefore, two sets of distance detectors may be responsible for detecting different regions and may not interfere with each other.

The first transmitter 6 and the receiver may satisfy the first distance, such that the receiver may receive the first target signal transmitted by the first transmitter 6 for the first target range.

The second transmitter 7 and the receiver may satisfy the second distance, such that the receiver may receive the second target signal transmitted by the second transmitter 7 for the second target range.

The distance of the first target range relative to the display screen 2 may be greater than the distance of the second target range relative to the display screen 2.

That is, the first target range may correspond to the long-distance detection region, the second target range may correspond to the short-distance detection region, the first distance between the first transmitter 6 and the receiver may satisfy the first distance, and the second distance between the second transmitter 7 and the receiver may satisfy the second distance, which may be all configured to ensure that the radiated target signal may be exited into corresponding target region, the signal strength may satisfy the detection requirement of corresponding category and the radiated target signal may be successfully received by the receiver, thereby ensuring subsequent recognition accuracy of whether an object is in the region.

In above-mentioned embodiments, the electronic device may include one receiver, which may be combined with different transmitters to form different types of detectors through time-division multiplexing. For example, the one receiver may be combined with the first transmitter 6 at the first moment to receive the target signal radiated by the first transmitter 6, combed with the second transmitter 7 at the second moment to receive the signal radiated by the second transmitter 7, and so on. In another embodiment, the electronic device may at least include two receivers; and two receivers may include the first receiver 8 which is located at the second position and corresponds to the second target region, and the second receiver 9 which is located at the third position and corresponds to the third target region, where the third target region may have same transmittance as the second target region.

The transmitter and the first receiver 8 may satisfy the first distance, and the transmitter and the second receiver 9 may satisfy the second distance, and the first distance may be greater than the second distance.

For example, the electronic device may include one transmitter and two receivers; the transmitter may radiate target signals of different energies; and two receivers may be configured to respectively receive a return signal of the high-energy target signal and a return signal of the low-energy target signal. The transmitter may be time-division multiplexed to form a long-distance object detector and a short-distance object detector with different receivers. When the electronic device includes two transmitters and two receivers, the transmitters and the receivers may be correspondingly combined, and each combination may include one transmitter and one receiver. The transmitter and the receiver in a same combination may be configured to cooperate to implement long-distance object detection or short-distance object detection.

For example, in one embodiment, two receivers may be the first receiver 8 and the second receiver 9; the first receiver 8 may be configured at the second position and correspond to the second target region; and the second receiver 9 may be configured at the third position and correspond to the third target region. The second target region and the third target region may be any two regions in the display screen 2. The two regions may be at different positions and have same transmittance, such as regions formed by removing only the copper sheet of the display screen 2. The distance between the transmitter and the first receiver 8 may be different from the distance between the transmitter and the second receiver 9. As mentioned above, the distance between the receiver and the transmitter may be proportional to the distance of the signal radiation. Therefore, detection of regions at different distances may be achieved by adjusting the distance between the transmitter and the receiver. The positions of each transmitter and each receiver may still need to be determined systematically through each viewing angle range and the position of the detection region as described above.

Furthermore, in one embodiment, the transmitter and the first receiver may satisfy the first distance, such that the first receiver 8 may receive the first target signal of the transmitter for the first target range; and the transmitter and the second receiver 9 may satisfy the second distance, such that the second receiver 9 may receive the second target signal of the transmitter for the second target range.

The distance of the first target range relative to the display screen 2 may be greater than the distance of the second target range relative to the display screen 2.

That is, through above-mentioned restrictions of the first distance and the second distance, it effectively ensures that the radiated target signal may be exited into corresponding target region, the signal strength may satisfy the detection requirement of corresponding category and the radiated target signal may be successfully received by the receiver, thereby ensuring subsequent recognition accuracy of whether an object is in the region.

In above-mentioned embodiments, optionally, the electronic device may include two groups of transmitters and receivers; one group of transmitter and receiver may be configured to detect whether an object is in the long-distance region, and another group of transmitter and receiver may be configured to detect whether an object is in the short-distance region. The distance between the transmitter and the receiver (in one group of transmitter and receiver) for long-distance detection may satisfy the first distance, and the distance between the transmitter and the receiver (in another group of transmitter and receiver) for short-distance detection may satisfy the second distance.

In one embodiment, the electronic device may be a structure including the first main body 13 and the second main body 14. Two main bodies may be rotatably connected to each other, such that the electronic device may have different attitudes. Or the display screen 2 may be a curved screen, and the electronic device may be a flexible structure that supports overall bending deformation, such that the electronic device may have different attitudes. The display screen 2 of the electronic device may be located outside the device, and the display screen 2 may also be configured inside the device. That is, the electronic device may be a dual-screen device or a single-screen device, which may not be limited in the present disclosure. In following embodiments, the electronic device may be formed by rotatably connecting the first main body 13 and the second main body 14, and the display screen 2 may be configured on the outside of the device, which may be taken as an example for illustration.

In one embodiment, the first main body 13 and the second main body 14 of the electronic device may each include the first side, the second side, the third side and the connecting side; and the connecting side may be the side where the two main bodies are rotatably connected to each other. The second side and the third side may be in parallel with each other and may correspond to the second side and the third side of another main body; and when the electronic device is unfolded into a planar state, two second sides and two third sides at corresponding positions may be in a collinear state. The first sides of two main bodies may be in parallel with each other and respectively located between the second side and the third side accordingly, which may correspond to the first end and the second end of the electronic device.

The electronic device in one embodiment may further include a sensor as shown in FIG. 1B, configured to obtain a target parameter, where the sensor may be a sensor capable of detecting the attitude of the device including an attitude sensor, a gravity sensor, a gyroscope and/or the like; and a processor (e.g., a CPU as shown in FIG. 1B), configured to perform different functions, which may be described in combination with different exemplary embodiments.

### Exemplary Embodiment One

In response to that the target parameter characterizes that the electronic device is in the first target attitude, the transmitter and receiver corresponding to the first target range may be enabled; the action of the object within the first target range may be determined through the first target signal; and in response to that the action satisfies the first target condition, the first target instruction may be responded.

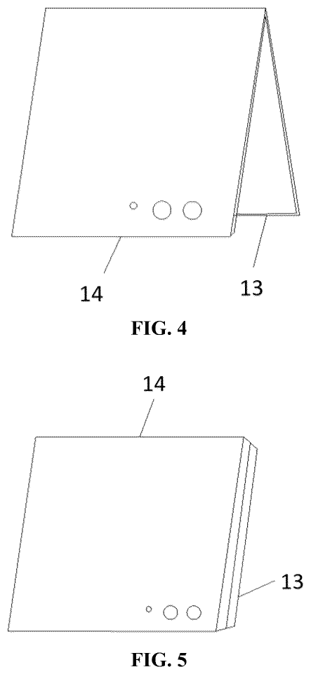

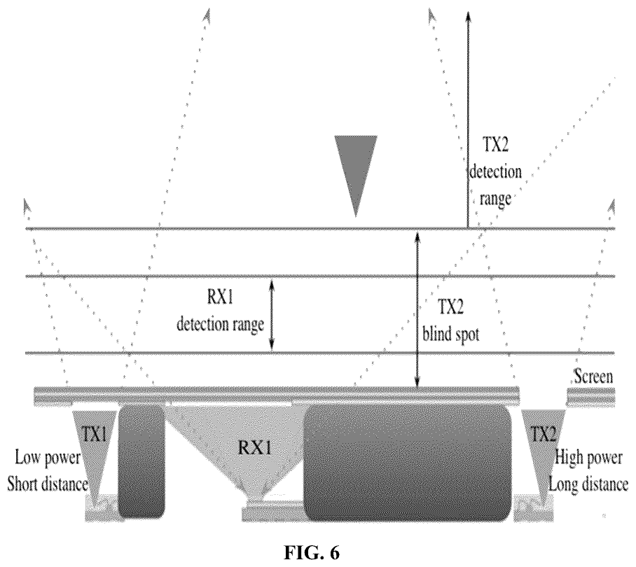

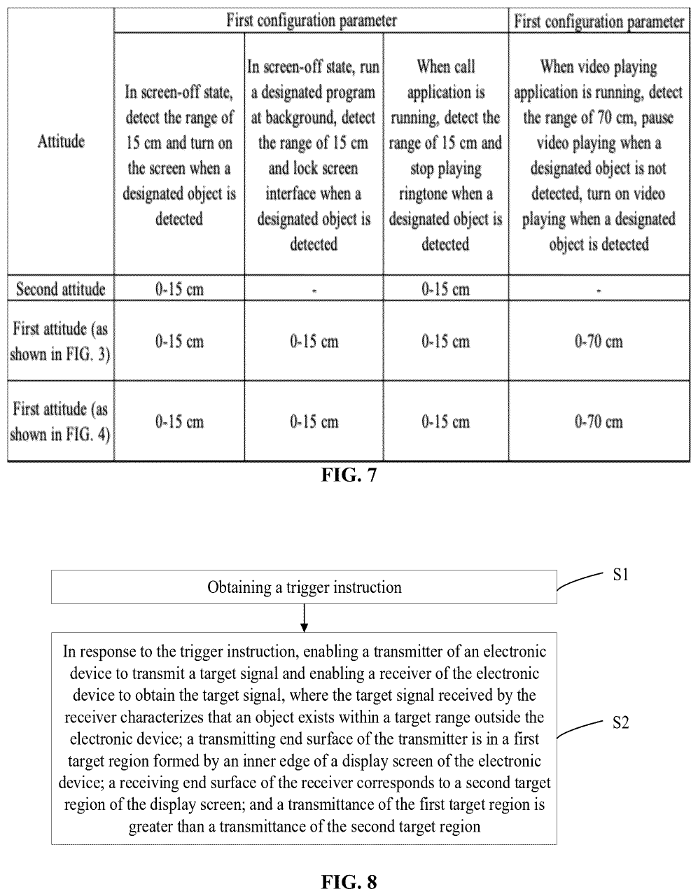

In one embodiment, as shown in FIGS. 3-4, the target attitude may be the relative position relationship between the first main body 13 and the second main body of the electronic device (same as below). In response to that the sensor senses that the target parameter characterizes that the electronic device is in the first target attitude (e. g., the electronic device may be in a “tent” state by bending the first main body 13 and the second main body 14), the first main body 13 and the second main body 14 may have an angle less than 90°, the connecting side of two main bodies may face upward, and the first sides of two main bodies may be against the desktop as supporting points; and at this point, the display screen 2 at the outer side of the electronic device may display pictures, and the user may watch the pictures just by standing the device on the desktop without holding the device. Or, the electronic device may be in the state shown in FIG. 3, the first main body 13 may be used as a supporting body, one side of the first main body 13 with the display screen 2 may be against the desktop, and the second main body 14 and the first main body 13 may have an angle of less than 90°, such that the second main body 14 may stand on the desktop through the first main body 13, the pictures may be displayed to the user through the display screen 2 at the outer side of the electronic device, and the user may not need to hold the device. In such state, the angle side between the two main bodies may be away from the user, that is, the connecting side of the two main bodies may face toward the user. In addition, the user may not hold the device, but view the pictures displayed by the device in a long-distance attitude. At this point, in order to facilitate the user to operate the device and avoid the user pressing the display screen 2 of the second main body 14 to cause the device to be unstable and fall over, the processor may control and enable the transmitter and the receiver corresponding to the first target range in response to the target parameter corresponding to current device attitude, that is, enable the long-distance region detector. At this point, the user may input the first gesture (or first action) within the first target range in front of the device, which may be cooperatively detected by the transmitter and the receiver which are enabled; that is, the receiver may determine the action of the object within the first target range by detecting returned first target signal. The processor may determine whether the action satisfies the first target condition by identifying such action, for example, whether the action is a gesture with a specified operation meaning, or whether the action corresponds to the first target instruction. In response to that the action satisfies the first target condition, the instruction inputted by the user may be determined to be the first target instruction, and the first target instruction may be responded.

### Exemplary Embodiment Two

In response to that the target parameter characterizes that the electronic device is in the first target attitude and the display screen 2 is in the first working state, the transmitter and receiver corresponding to the first target range may be enabled; the action of the object within the first target range may be determined through the first target signal; and in response to that the action satisfies the second target condition, the display screen 2 may be controlled to be in the second working state, where the power consumption of the first working state may be lower than the power consumption of the second working state.

Exemplarily, in response to that the target parameter characterizes that the electronic device is in the first target attitude and current display screen 2 is monitored to be in the first working state, the power consumption of the first working state may be lower than the power consumption of the second working state of the display screen 2. For example, the first working state may be a state including an always-on state, a low-power display state or the like. At this point, the processor may control and enable the transmitter and the receiver corresponding to the first target range. That is, the long-distance region detector may be enabled to detect objects which are within the first target range and outside the device. At this point, the user may input the second gesture (or second action) within the first target range in front of the device, which may be cooperatively detected by the transmitter and the receiver which are enabled; that is, the receiver may determine the action of the object within the first target range by detecting returned first target signal. The processor may determine whether the action satisfies the second target condition by identifying such action, for example, whether the action is a gesture with a specified operation meaning, or whether the action corresponds to the second target instruction. In response to that the action satisfies the second target condition, the instruction inputted by the user may be determined to be the second target instruction; and the second target instruction may be responded to switch the display screen 2 to the second working state, for example, the display screen 2 may be in normal display state.

### Exemplary Embodiment Three

In response to that the target parameter characterizes that the electronic device is in the first target attitude and the first target application is in the first state, the transmitter and receiver corresponding to the first target range may be enabled; the action of the object within the first target range may be determined through the first target signal; and in response to that the action satisfies the third target condition, the first target application may be controlled to be in the second state, where the first target application in the first state may output target content, and the first target application in the second state may stop outputting target content corresponding to next moment.

For example, the electronic device may include the first target application having the first state and the second state. The first state may be a state that the first target application continuously outputs the target content, and the second state may be a state that the first target application stops outputting the target content corresponding to next moment. It's assumed that the first target application is a player, the player may be in above-mentioned first state when the play is in normal playing state; and when the player is paused or exited, the player may stop currently outputted frame or close the display interface, the player may be in the state that stops continuing to output next frame, and the state of the first target application at this point may be the second state. For another example, the first target application may be an alarm; the alarm may be in the first state when the alarm is ringing; and when the ringing is paused or the alarm program is exited, the first target application may no longer continue to output the ringtone, and the state of the first target application at this point may be the second state. In response to that the processor determines that the electronic device is in the first target attitude through the target parameter and detects that the first target application is in the first state, the processor may enable the transmitter and the receiver corresponding to the first target range. That is, the transmitter and the receiver for long-distance detection may be enabled for detecting objects which are within the first target range and outside the device. At this point, the user may input the third gesture (or third action) within the first target range in front of the device, which may be cooperatively detected by the transmitter and the receiver which are enabled; that is, the receiver may determine the action of the object within the first target range by detecting returned first target signal. The processor may determine whether the action satisfies the third target condition by identifying such action, for example, whether the action is a gesture corresponding to the third target instruction. In response to that the action is the gesture corresponding to the third target instruction, the instruction inputted by the user may be determined to be the third target instruction; and the third target instruction may be responded to control the first target application to be in the second state, for example, pausing or closing the first target application or the like.

### Exemplary Embodiment Four

In response to that the target parameter characterizes that the electronic device is in the second target attitude, the transmitter and the receiver corresponding to the second target range may be enabled; the second target signal may be configured to determine that an object is within the second target range; and the electronic device may be controlled to be in the target working mode.

In one embodiment, when the processor determines that the electronic device is in the second target attitude based on obtained target parameter through the detection of the sensor, the transmitter and the receiver corresponding to the second target range may be enabled, that is, the transmitter and the receiver for short-distance detection may be enabled. As shown in FIG. 5, the second target attitude in one embodiment may be the “closed” attitude of the electronic device; that is, at this point, the first main body 13 and the second main body 14 may rotate and approach to corresponding closed state, as shown in FIG. 5. In current state, the processor may directly assume that the electronic device may be in a state of waiting for use, for example, the user may place the mobile phone on the desktop or the like. Therefore, the gestures applied by the user at close range (e.g., picking up the electronic device, waving at close range above the electronic device and/or the like) may be detected in a timely and accurate manner by enabling the short-distance detector. When the processor determines that an object is within the second target range by obtaining the second target signal fed back by the receiver, the processor may promptly control the electronic device to be in the target working mode, such as in a wake-up mode. Or, the processor may further detect whether the electronic device is in a stable position state, and use such state to systematically determine which target working mode the electronic device should be in. For example, in response to the electronic device is in a stable position state, the processor may control the target working mode to be a wake-up mode, a normal working mode, a satisfying mode or the like; and in response to the electronic device is in an unstable position state, the processor may control the target working mode to be a pocket mode or the like, which may not be limited in the present disclosure.

### Exemplary Embodiment Five

In response to that the target parameter characterizes that the electronic device is in the third target attitude, the transmitter and the receiver corresponding to the first target range may be disabled; in response to that the electronic device is in the third target attitude and the second target application is in working state, the transmitter and the receiver corresponding to the second target range may be enabled; and the second target signal may be configured to determine that an object is within the second target range, and the second target instruction may be responded.

Two solutions may be provided in one embodiment. The first solution may be that when the processor determines that the electronic device is in the third target attitude based on the target parameter (e.g., the third target attitude is still above-mentioned “closed” state), the processor may determine that the electronic device is in the short-distance use mode. At this point, the processor may automatically choose to disable the transmitter and the receiver corresponding to the first target range, that is, to disable the transmitter and the receiver used for long-distance detection, which may save energy consumption. The processor may be configured to control the transmitter and the receiver used for short-distance detection according to the solution of previous embodiment. The second solution in one embodiment may be that in response to that the electronic device is in the third target attitude (e.g., the “closed” state) and the second target application is in the working state (e.g., the second target application may be a call application), at this point, the processor may enable the transmitter and the receiver corresponding to the second target range; that is, the transmitter and the receiver for short-distance detection may be enabled. In such way, the target signal to the second target range may be radiated based on the short-distance detection function, and corresponding second target signal may be obtained. The processor may determine that an object is within the second target range based on the second target signal, and the second target instruction may be directly responded. Taking the second target application as a call application as an example, when it determines that the user will answer the call based on the second target signal, the second target instruction may be responded, and the screen backlight may be controlled to be turned off, such that the screen may be in a screen-off state (e.g., black screen state).

Based on above-mentioned embodiments, as shown in FIG. 7, in another embodiment, the signal energies transmitted by TX2 (e.g., the long-distance transmitter) may be more than one, for example, may be configured as at least two types. Taking the description shown in FIG. 7 as an example, the signal transmission energies of the long-distance transmitter in one embodiment may include two types, such that the transmitter may transmit energy to the range of 15 cm and the range of 70 cm. The 15 cm and 70 cm mentioned herein may be not fixed values and may be adjusted according to actual conditions. Obviously, in the absence of the short-distance transmitter of TX1, the TX2 may also form TX1 to achieve short-distance signal transmission. In actual application, referring to FIG. 7, when the electronic device is in the first target attitude (e.g., the attitude shown in FIG. 3 and FIG. 4) and the system determines that the device is in the first target attitude (or other target attitude), the system may dynamically adjust the energy of the signal transmitted by TX2 according to the application currently running on the device, that is, adjust the configuration of TX2 based on different configuration parameters. In such way, TX2 may transmit the signal with required energy to detect whether a designated object is in corresponding range.

For example, in the first target attitude, in response to that the video playing application is running, the long-distance transmitter may be configured based on the second configuration parameter, thereby controlling the long-distance transmitter to transmit the high-energy signal to detect whether a designated object is within the range of 70 cm, for example, detect whether the user is within the range of 70 cm. In response to that the user is outside the range of 70 cm, that is, no designated object is within the range of 70 cm, the application may be controlled to pause the playing; and when it determines that the user returns to the range of 70 cm, the application may be controlled to continue playing.

Or, in the first target attitude, in response to that the call application is running, the long-distance transmitter may be configured based on the first configuration parameter, thereby controlling the long-distance transmitter to transmit the medium-energy signal to detect whether a designated object is within the 15 cm range, for example, detect whether the user's gesture is detected within the 15 cm range, whether there is a user, and/or the like. In response to that the designated object is within the 15 cm range, the application may be controlled to stop the output of the ringtone, the volume of the ringtone may be controlled to be reduced and/or the like.

Or, when the device is in the second target attitude (e.g., the attitude shown in FIG. 5, or the first target attitude), in response to that the device is currently in the always-on state, the long-distance transmitter may be controlled to transmit the medium-energy signal or the high-energy signal based on the first configuration parameter or the second configuration parameter according to the pre-configured information, thereby detecting whether a user is within the target range. In response to that the user is within the target range, the screen may be turned on. Or, in above-mentioned attitude, when the device runs functions or applications such as screen projection and the like, the long-distance transmitter may be configured based on the first configuration parameter, thereby controlling the long-distance transmitter to transmit the medium-energy signal. In such way, in the always-on state, the device may always monitor whether a user inputted gesture action is within 15 cm or whether there is a user. In response to that the user inputted gesture action is within 15 cm or there is a user, the screen may be turned on and the lock screen interface may be displayed in time, and the user may not need to perform touch operations, which may be convenient for the user to use the electronic device.

As shown in FIG. 8, another embodiment of the present disclosure further provides a control method. The control method may include S1 of obtaining a trigger instruction; and S2 of in response to the trigger instruction, enabling the transmitter to transmit the target signal and enabling the receiver to obtain the target signal. The target signal received by the receiver may characterize that a presence of an object is in the target range outside the device.

The transmitting end surface of the transmitter may be in the first target region formed by the inner edge of the device display screen, the receiving end surface of the receiver may correspond to the second target region of the display screen, and the transmittance of the first target region may be greater than the transmittance of the second target region.

Above-mentioned method of one embodiment may be applied to the electronic device as described above. In the solution described in one embodiment, the processor may be configured to control the operation of the transmitter and the receiver in response to the trigger instruction, thereby detecting the attitude of the object and whether an object is in the target range outside the device and the like. The trigger instruction may be generated by the system in the electronic device based on current attitude and working state of the electronic device detected by the sensor; and the trigger instructions may be different for different device attitudes and working states.

In one embodiment, in response to the trigger instruction, enabling the transmitter to transmit the target signal and enabling the receiver to obtain the target signal may include following exemplary steps.

At one operational step, the transmitter may be enabled to transmit the first target signal with the first energy and the second target signal with the second energy. When the first target signal and the second target signal are different, the first target signal of the first energy may correspond to the first target range, the second target signal of the second energy may correspond to the second target range, and the first energy may be greater than the second energy.

At one operational step, the first receiver may be enabled to receive the first target signal.

At one operational step, the second receiver may be enabled to receive the second target signal.

The first receiver may correspond to the second target region, the second receiver may correspond to the third target region, and the transmittance of the second target region may be same as the transmittance of the third target region.

For example, the electronic device may include eon transmitter and two receivers; and the transmitter and different receivers may be respectively combined to form the short-distance object detector and the long-range object detector. Two receivers may be configured in the display screen and respectively correspond to the second target region and the third target region of the display screen. The transmittance of two target regions may be same, such that two receivers may be in same environment; and in addition to own performance of two receivers, the influence of the external environment on the receiving ability may be same.

For example, in one embodiment, the transmitter may cooperate with the first receiver to form the long-distance object detector, and the transmitter may cooperate with the second receiver to form the short-distance object detector. The transmitter may select to cooperate with different receivers at different times to form detectors with corresponding functions through command control, and the signal energy transmitted by the transmitter may be also implemented based on command control.

Exemplarily, when the electronic device is in the first target attitude described above, the first trigger instruction may be generated; and in response to the first trigger instruction, the transmitter may be enabled to transmit the first target signal with the first energy, and the first receiver may be enabled to receive the first target signal.

When the electronic device is in the first target attitude, and the display screen of the electronic device is in a low power first working state (e.g., always-on state or the like), the transmitter may be enabled to transmit the first target signal with the first energy, and the first receiver may be enabled to receive the first target signal.

When the electronic device is in the first target attitude and the electronic device runs the first target application (e.g., a video player or the like), the transmitter may be enabled to transmit the first target signal with the first energy, and the first receiver may be enabled to receive the first target signal.

When the electronic device is in the second target attitude described above (e.g., the tent attitude) or the third target attitude (e.g., the closed attitude), the transmitter may be enabled to transmit the second target signal with the second energy, and the second receiver may be enabled to receive the second target signal.

When the electronic device is in the second target attitude or the third target attitude and the electronic device runs the second target application (e.g., the call application), the transmitter may be enabled to transmit the second target signal with the second energy, and the second receiver may be enabled to receive the second target signal.

When the electronic device changes attitude or receives the instruction inputted by the user for switching the detection region, or based on the time-division multiplexing rule, in response to the transmission state of the transmitter at previous moment, the switching of the transmission mode of the transmitter at current moment (embodied as energy differences of the transmitted signal) and the switching of the receiver may be implemented.

In another embodiment, the electronic device may include two transmitters, which may respectively transmit the first target signal and the second target signal of different energies; and the electronic device may include one receiver, which may be time-division multiplexed to cooperate with different transmitters to form the long-distance object detector and the short-distance object detector. For example, in response to the trigger instruction, enabling the transmitter to transmit the target signal and enabling the receiver to obtain the target signal may include following exemplary steps.

At one operational step, the first transmitter may be enabled to transmit the first target signal with the first energy.

At one operational step, the second transmitter may be enabled to generate the second target signal with the second energy. The first target signal of the first energy may correspond to the first target range, the second target signal of the second energy may correspond to the second target range, and the first energy may be greater than the second energy.

At one operational step, the receiver may be enabled to receive the first target signal and the second target signal.

The first transmitter may correspond to the first target region, the second transmitter may correspond to the third target region, and the transmittance of the first target region may be greater than the transmittance of the third target region.

For example, when the electronic device is in the first target attitude described above, the first trigger instruction may be generated; and in response to the first trigger instruction, the first transmitter may be enabled to transmit the first target signal, and the receiver may be enabled to receive the first target signal.

When the electronic device is in the first target attitude and the display screen of the electronic device is in a low power first working state (e.g., always-on state or the like), the first transmitter may be enabled to transmit the first target signal, and the receiver may be enabled to receive the first target signal.

When the electronic device is in the first target attitude and the electronic device runs the first target application (e.g., a video player or the like), the first transmitter may be enabled to transmit the first target signal, and the receiver may be enabled to receive the first target signal.

When the electronic device is in the second target attitude described above (e.g., the tent attitude) or the third target attitude (e.g., the closed attitude), the second transmitter may be enabled to transmit the second target signal, and the receiver may be enabled to receive the second target signal.

When the electronic device is in the second target attitude or the third target attitude and the electronic device runs the second target application (e.g., the call application), the second transmitter may be enabled to transmit the second target signal, and the receiver may be enabled to receive the second target signal.

Similarly, when the electronic device changes attitude or receives the instruction inputted by the user for switching the detection region, or based on the time-division multiplexing rule, in response to the transmitter running at previous moment, corresponding transmitter may be controlled to perform signal transmission operation at current moment. That is, the transmitter operation may be switched and controlled to achieve object detection within different ranges.

Various embodiments of the present disclosure further provide a storage medium. The storage medium may include a stored program; and when the program is running, the device, including the storage medium, may be controlled to perform the control method as described in any of above-mentioned embodiments.

Various embodiments of the present disclosure further provide a computer program product. The computer program product may be tangibly stored on a computer-readable medium and include computer-readable instructions. When the computer-executable instructions are executed, at least one processor may be enabled to perform the control method as described in any of above-mentioned embodiments. It may be understood that all solutions in various embodiments may have corresponding technical effect in above-mentioned method embodiments, which may not be described in detail herein.

Various embodiments of the present disclosure provide a non-transitory computer-readable storage medium containing a computer program that when being executed, causes one or more processors to perform a control method. The control method includes obtaining a trigger instruction; and in response to the trigger instruction, enabling a transmitter of an electronic device to transmit a target signal and enabling a receiver of the electronic device to obtain the target signal, where the target signal, received by the receiver, is configured to characterize that a presence of an object is within a target range outside the electronic device. A transmitting end surface of the transmitter is in a first target region formed by an inner edge of a display screen of the electronic device, a receiving end surface of the receiver corresponds to a second target region of the display screen, and a transmittance of the first target region is greater than a transmittance of the second target region.

It should be noted that the computer storage medium of the present disclosure may be a computer-readable signal medium or a computer-readable storage medium or any combination thereof. Exemplarily, computer-readable media may be, but may be not limited to, electrical, magnetic, optical, electromagnetic, infrared or semiconductor systems, apparatuses or components, or any combination thereof. Exemplarily, computer-readable storage media may include, but may be not limited to, an electrical connection with one or more wires, a portable computer disk, a hard disk, a random access storage medium (RAM), a read-only storage medium (ROM), an erasable programmable read-only storage medium (EPROM or flash memory), an optical fiber, a portable compact disk read-only storage medium (CD-ROM), an optical storage medium, a magnetic storage medium, or any suitable combination thereof. In the present disclosure, the computer-readable storage medium may be any tangible medium containing or storing programs that may be used by or in combination with instruction execution systems, apparatuses or devices. In the present disclosure, the computer-readable signal medium may include data signals propagated in a baseband or as part of a carrier wave, which may carry computer-readable program code. Such propagated data signals may take a variety of forms, including but not limited to electromagnetic signals, optical signals, or any suitable combination thereof. The computer-readable signal medium may also be any computer-readable medium other than the computer-readable storage medium. The computer-readable medium may send, propagate or transmit programs configured to be used by or in combination with instruction execution systems, apparatuses or devices. The program code contained on the computer-readable medium may be transmitted using any appropriate medium, including but not limited to wireless, antenna, optical cable, RF (radio frequency) or the like, or any suitable combination thereof.

The above may be merely exemplary embodiments of the present disclosure, which may not limit the present disclosure. The protection scope of the present disclosure may be defined by the claims. Those skilled in the art may make various modifications or equivalent substitutions to the present disclosure within the essence and protection scope of the present disclosure; and such modifications or equivalent substitutions shall also fall within the protection scope of the present disclosure.

What is claimed is:

1. An electronic device, comprising:
a frame body;
a display screen, disposed on an outer surface of the frame body, wherein the display screen includes an inner edge and an outer edge;
a transmitter, disposed at a first position of the frame body and configured to transmit a target signal, wherein a transmitting end surface of the transmitter is in a first target region formed by the inner edge of the display screen; and
a receiver, disposed at a second position of the frame body and configured to receive the target signal, wherein a receiving end surface of the receiver corresponds to a second target region of the display screen; a transmittance of the first target region is greater than a transmittance of the second target region; and the target signal, received by the receiver, is configured to characterize that a presence of an object is within a target range outside the electronic device.

2. The electronic device according to claim 1, further including:
a shared part, sharing the first target region with the transmitter, wherein the shared part includes one of following:
a first light-emitting element, disposed at a third position of the frame body;
a first camera, disposed at a fourth position of the frame body; or
a second camera, disposed at a fifth position of the frame body, wherein the transmitter is between the fourth position and the fifth position.

3. The electronic device according to claim 2, further comprising:
at least two transmitters, wherein the at least two transmitters include:
a first transmitter at the first position and corresponding to the first target region; and
a second transmitter at the third position and corresponding to the third target region, wherein a transmittance of the third target region is same as the transmittance of the second target region, wherein:
a distance between the first transmitter and the receiver satisfies a first distance, a distance between the second transmitter and the receiver satisfies a second distance, and the first distance is greater than the second distance.

4. The electronic device according to claim 3, wherein:
the distance between the first transmitter and the receiver satisfies the first distance, such that the receiver is capable of receiving a first target signal transmitted by the first transmitter for a first target range; and
the distance between the second transmitter and the receiver satisfies the second distance, such that the receiver is capable of receiving a second target signal transmitted by the second transmitter for a second target range; wherein:
a distance between the first target range and the display screen is greater than a distance between the second target range and the display screen.

5. The electronic device according to claim 2, further comprising:
at least two receivers, wherein the at least two receivers include:
a first receiver at the second position and corresponding to the second target region; and
a second receiver at the third position and corresponding to a third target region, wherein a transmittance of the third target region is same as the transmittance of the second target region, wherein:
a distance between the transmitter and the first receiver satisfies a first distance, a distance between the transmitter and the second receiver satisfies a second distance, and the first distance is greater than the second distance.

6. The electronic device according to claim 5, wherein:
the distance between the transmitter and the first receiver satisfies the first distance, such that the first receiver is capable of receiving a first target signal of the transmitter for a first target range; and
the distance between the transmitter and the second receiver satisfies the second distance, such that the second receiver is capable of receiving a second target signal of the transmitter for a second target range, wherein:
a distance between the first target range and the display screen is greater than a distance between the second target range and the display screen.

7. The electronic device according to claim 4, further including:
a processor; and
a sensor, configured to obtain a target parameter.

8. The electronic device according to claim 7, wherein the processor is configured to:
in response to that the target parameter characterizes that the electronic device is in a first target attitude, enable a transmitter and a receiver corresponding to the first target range;
determine an action of an object within the first target range through the first target signal; and
in response to that the action satisfies a first target condition, respond to a first target instruction.

9. The electronic device according to claim 7, wherein the processor is configured to:
in response to that the target parameter characterizes that the electronic device is in a first target attitude and the display screen is in a first working state, enable a transmitter and a receiver corresponding to the first target range;
determine an action of an object within the first target range through the first target signal; and
in response to that the action satisfies a second target condition, control the display screen to be in a second working state, wherein power consumption of the first working state is lower than power consumption of the second working state.

10. The electronic device according to claim 7, wherein the processor is configured to:
in response to that the target parameter characterizes that the electronic device is in a first target attitude and a first target application is in a first state, enable a transmitter and a receiver corresponding to the first target range;
determine an action of an object within the first target range through the first target signal; and
in response to that the action satisfied a third target condition, control the first target application to be in a second state, wherein the first target application in the first state outputs target content, and the first target application in the second state stops outputting target content corresponding to a next moment.

11. The electronic device according to claim 7, wherein the processor is configured to:
in response to that the target parameter characterizes that the electronic device is in a second target attitude, enable a transmitter and a receiver corresponding to the second target range; and
determine that a presence of an object is within the second target range through the second target signal and controlling the electronic device to be in a target working mode.

12. The electronic device according to claim 7, wherein the processor is configured to:
in response to that the target parameter characterizes that the electronic device is in a third target attitude, disable a transmitter and a receiver corresponding to the first target range;
in response to that the electronic device is in a third target attitude and a second target application is in a working state, enable a transmitter and a receiver corresponding to the second target range; and
determine that a presence of an object is within the second target range through the second target signal, and responding to a second target instruction, wherein:
a target attitude is a relative positional relationship between a first main body and a second main body of the electronic device.

13. A control method, comprising:
obtaining a trigger instruction; and
in response to the trigger instruction, enabling a transmitter of an electronic device to transmit a target signal and enabling a receiver of the electronic device to obtain the target signal, wherein the target signal, received by the receiver, is configured to characterize that a presence of an object is within a target range outside the electronic device, wherein:
a transmitting end surface of the transmitter is in a first target region formed by an inner edge of a display screen of the electronic device, a receiving end surface of the receiver corresponds to a second target region of the display screen, and a transmittance of the first target region is greater than a transmittance of the second target region.

14. The method according to claim 13, wherein in response to the trigger instruction, enabling the transmitter to transmit the target signal and enabling the receiver to obtain the target signal includes:
enabling the transmitter to transmit a first target signal with a first energy and a second target signal with a second energy, wherein when the first target signal transmitted and the second target signal transmitted are different, the first target signal with the first energy corresponds to a first target range, the second target signal with the second energy corresponds to a second target range, and the first energy is greater than the second energy;
enabling a first receiver to receive the first target signal; and
enabling a second receiver to receive the second target signal, wherein:
the first receiver corresponds to the second target region, the second receiver corresponds to a third target region, and the transmittance of the second target region is same as a transmittance of the third target region.

15. The method according to claim 13, wherein in response to the trigger instruction, enabling the transmitter to transmit the target signal and enabling the receiver to obtain the target signal includes:
enabling a first transmitter to transmit a first target signal with a first energy;
enabling a second transmitter to transmit a second target signal with a second energy, wherein the first target signal with the first energy corresponds to a first target range, the second target signal with the second energy corresponds to a second target range, and the first energy is greater than the second energy; and
enabling the receiver to receive the first target signal and the second target signal, wherein:
the first transmitter corresponds to the first target region, the second transmitter corresponds to a third target region, and the transmittance of the first target region is greater than a transmittance of the third target region.

16. The method according to claim 14, further including:
when the electronic device is in a first target attitude, generating a first trigger instruction; and in response to the first trigger instruction, enabling the transmitter to transmit the first target signal with the first energy, and enabling the first receiver to receive the first target signal.

17. The method according to claim 14, further including:
when the electronic device is in a first target attitude and the display screen is in a first working state, enabling the transmitter to transmit the first target signal with the first energy, and enabling the first receiver to receive the first target signal.

18. The method according to claim 14, further including:
when the electronic device is in a first target attitude and the electronic device runs a first target application, enabling the transmitter to transmit the first target signal with the first energy, and enabling the first receiver to receive the first target signal.

19. The method according to claim 14, further including:
when the electronic device is in a second target attitude or a third target attitude, enabling the transmitter to transmit the second target signal with the second energy, and enabling the second receiver to receive the second target signal.

20. A non-transitory computer-readable storage medium containing a computer program that when being executed, causes one or more processors to perform:
obtaining a trigger instruction; and
in response to the trigger instruction, enabling a transmitter of an electronic device to transmit a target signal and enabling a receiver of the electronic device to obtain the target signal, wherein the target signal, received by the receiver, is configured to characterize that a presence of an object is within a target range outside the electronic device, wherein:
a transmitting end surface of the transmitter is in a first target region formed by an inner edge of a display screen of the electronic device, a receiving end surface of the receiver corresponds to a second target region of the display screen, and a transmittance of the first target region is greater than a transmittance of the second target region.
